(19) United States
(12) Patent Application Publication
(10) Pub. No.: US 2007/0028959 A1
(43) Pub. Date: Feb. 8, 2007

(54) Electrode for photoelectric conversion device containing metal element and dye-sensitized solar cell using the same

(75) Inventors: Wha-Sup Lee, Suwon-si (KR); Ji-Won Lee, Suwon-si (KR); Kwong-Soon Ahn, Suwon-si (KR); Jae-Man Choi, Suwon-si (KR); Byong-Chaol Shin, Suwon-si (KR); Joung-Won Park, Suwon-si (KR)

Correspondence Address: STEIN, MCEWEN & BUI, LLP, 1400 EYE STREET, NW, SUITE 300, WASHINGTON, DC, 20005, US

(73) Assignee: Samsung SDI Co., Ltd, Suwon-si (KR)

(21) Appl. No.: 11/497,332

(22) Filed: Aug. 2, 2006

(30) Foreign Application Priority Data
Aug. 2, 2005 (KR) 10-2005-0070637

(51) Int. Cl. H01L 31/00

(52) U.S. Cl. 136/252

(57) ABSTRACT

An electrode for a photoelectric conversion device includes a transparent substrate and a transparent conductive film, in which the transparent conductive film contains an added metal element on at least one surface thereof, and the surface resistance of the transparent substrate is reduced in order to improve the photoelectric conversion efficiency. A dye-sensitized solar cell includes the electrode.

### CROSS-REFERENCE TO RELATED APPLICATIONS

This application claims the benefit of Korean Application No. 2005-70637, filed on Aug. 2, 2005 in the Korean Intellectual Property Office, the disclosure of which is incorporated herein by reference.

### BACKGROUND OF THE INVENTION

1. Field of the Invention

Aspects of the present invention relate to an electrode for a photoelectric conversion device containing a metal element, and a dye-sensitized solar cell using the same. In particular, aspects of the present invention relate to an electrode for a photoelectric conversion device, having a reduced surface resistance of the substrate of the electrode in order to improve the photoelectric conversion efficiency, and a dye-sensitized solar cell using the same.

2. Description of the Related Art

In an attempt to address the problem of the finite nature of existing fossil fuels, research has been conducted to find renewable energy sources. In particular, extensive research has been conducted to utilize natural energy such as wind energy, nuclear energy, solar energy, and so on, to replace the petroleum resources that are expected to undergo exhaustion within several decades. Among the possible replacements, solar cells utilizing solar energy are promising because, unlike other energy resources, this particular energy resource is unlimited and is environmentally friendly. Solar cells were first developed in 1983, and silicon solar cells have recently come into the spotlight.

However, silicon solar cells have very high production costs, which make them difficult to implement in practice. Further, there are difficulties in improving the cell efficiency of the silicon solar cells. In order to overcome these problems, research is being carried out to develop dye-sensitized solar cells that can be produced at significantly lower costs.

Unlike silicon solar cells, dye-sensitized solar cells are electrochemical solar cells employing photosensitive dye molecules that are capable of generating electron-hole pairs by absorbing visible light, and a transition metal oxide which transfers generated electrons, as the main constituent materials. A representative example of such dye-sensitized solar cells is a dye-sensitized solar cell suggested by Graetzel et al. in Switzerland in 1991 (Nature, 353(24) 737-740 (Oct. 24, 1991)). Since the dye-sensitized solar cell of Graetzel et al. can be produced at a lower production cost per unit electric power than conventional silicon solar cells, the dye-sensitized solar cell is attracting much attention as a possible replacement for existing solar cells.

FIG. 1 is a diagram illustrating the operating principle of a general dye-sensitized solar cell, in which absorption of sunlight by dye molecules 5 leads to an electronic transition of the dye molecules 5 from the ground state to an excited state so as to provide electron-hole pairs. The electrons in the excited state are injected into the conduction band at interfaces of titanium oxide particles, and the injected electrons are transported through the interface of a transparent electrode 1 and then an external circuit 3 to a counter electrode 2.

On the other hand, the dye molecules 5 which have been oxidized as a result of the electronic transition are reduced by the oxidation-reduction couple in an electrolyte 4, and the oxidized ions undergo a reduction reaction with the electrons that have reached the interface of the counter electrode 2 to attain charge neutrality, thus allowing the dye-sensitized solar cell to operate. As such, the dye-sensitized solar cell is subject to an electrochemical principle of operating through interfacial reactions, unlike conventional p-n junction type silicon solar cells. Accordingly, a critical technology is the control of the properties that allow smooth charge transfer between the interfaces of the constituent layers of the dye-sensitized solar cell. FIG. 2 illustrates a substantial laminate structure that is applicable to the dye-sensitized solar cell, the operating principle of which is illustrated in FIG. 1.

A dye-sensitized solar cell should be capable of controlling the properties for the operation of the dye-sensitized solar cell as schematically illustrated in FIG. 1, and also should be capable of collecting the electrons generated by the solar cell in the presence of light, into the electrode without much loss. Inter alia, the electron transfer occurring at the interfaces between a metal oxide (in this case, the titanium oxide particles) and a transparent conductive photocathode (in this case, the transparent electrode) has a significant impact on the properties of the dye-sensitized solar cell. The dye molecules that are photoexcited in the presence of light generate charges, and when electrons are transferred to the titanium oxide particles, these electrons in turn move toward the transparent electrode. Here, when a surface resistance of the transparent electrode is high, the electron transfer is not smooth, and sufficient charge collection is not achieved. As a result, some properties of the dye-sensitized solar cell, such as open circuit voltage (V_{oc}), short circuit current (I_{sc}), and fill factor (FF) are deteriorated. Therefore, in order to allow the transparent electrode to receive the generated electrons without significant loss, there is a need for improvements in the structure of the transparent electrode.

### SUMMARY OF THE INVENTION

Aspects of the present invention provide an electrode for a photoelectric conversion device, which has reduced surface resistance.

Aspects of the present invention also provide a dye-sensitized solar cell using the electrode for a photoelectric conversion device.

According to an aspect of the present invention, there is provided an electrode for a photoelectric conversion device, the electrode comprising a transparent substrate and a transparent conductive film, in which the transparent conductive film contains an added metal element.

The amount of the added metal element contained in the transparent conductive film may be 0.01 to 50% by weight, based on the total amount of the components of the transparent conductive film.

The added metal element contained in the transparent conductive film may be at least one element selected from the group consisting of the metals belonging to Group 13 and Group 14, and transition metals.

The added metal element incorporated in the transparent conductive film may be at least one element selected from the group consisting of Al, Ni, Cr, Cu, Fe, Ti, Ta, Sn, In, Pt, Au, Ag and Ru.

According to another aspect of the present invention, there is provided a dye-sensitized solar cell using the electrode for a photoelectric conversion device.

According to another aspect of the present invention, a dye-sensitized solar cell includes a transparent electrode having a transparent conductive film formed on a transparent substrate, the transparent conductive film containing a metal component of the transparent conductive film, and an added metal element to reduce a surface resistance of the transparent electrode.

According to another aspect of the present invention, a method of forming an electrode of a dye-sensitive solar cell includes incorporating a metal element to a transparent conductive film, coating the transparent conductive film having the incorporated metal elements to a transparent substrate, and calcining the transparent substrate having the incorporated metal elements at a temperature of about 150° C.

Additional aspects and/or advantages of the invention will be set forth in part in the description which follows and, in part, will be obvious from the description, or may be learned by practice of the invention.

### BRIEF DESCRIPTION OF THE DRAWINGS

These and/or other aspects and advantages of the present invention will become apparent and more readily appreciated from the following description of the various aspects of the present invention, taken in conjunction with the accompanying drawings of which:

FIG. 1 is a schematic diagram illustrating the operating principle of a general dye-sensitized solar cell;

FIG. 2 is a schematic diagram illustrating the basic structure of a dye-sensitized solar cell; and

FIG. 3 is a schematic diagram illustrating the structure of a dye-sensitized solar cell according to an aspect of the present invention.

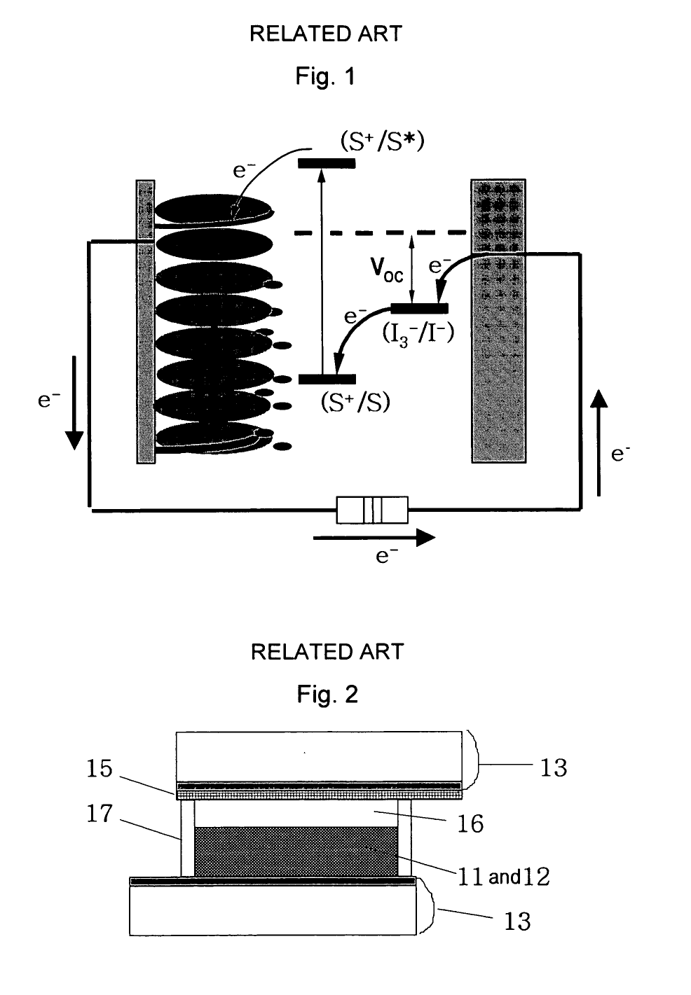

### DETAILED DESCRIPTION OF THE EMBODIMENTS

Reference will now be made in detail to various aspects of the present invention, examples of which are illustrated in the accompanying drawings, wherein like reference numerals refer to the like elements throughout. The aspects are described below in order to explain the present invention by referring to the figures.

Aspects of the present invention include an electrode for a photoelectric conversion device attaining an improved photoelectric conversion efficiency, by reducing the surface and/or electric resistance of a transparent electrode, which is used as the electrode for a photoelectric conversion device making use of an electrochemical principle involving interfacial reactions, so as to guide the electrons generated by dye molecules in the presence of light to the transparent electrode without significant loss, and also by improving the charge collection properties, and a dye-sensitized solar cell using the same.

In various aspects of the present invention, a transparent conductive film composed of a transparent conductive material is formed on a transparent substrate and the film and the substrate are used in the electrode for a photoelectric conversion device that is used in dye-sensitized solar cells or the like. Thus, according to an aspect of the present invention, a metal element is incorporated into the transparent conductive film to reduce the surface and/or electric resistance of the transparent electrode.

The metal element (added metal element) incorporated into the transparent conductive film may be any metal having excellent electric conductivity, and may be at least one metal selected from the group consisting of the metals belonging to Group 13 and Group 14, and transition metals, such as at least one metal selected from the group consisting of Al, Ni, Cr, Cu, Fe, Ti, Ta, Sn, In, Pt, Au, Ag and Ru.

The amount of the metal element contained in the transparent conductive film may be 0.01 to 50% by weight, based on the total amount of the components of the transparent conductive film, which excludes the transparent substrate. When the amount of the metal element is greater than 50% by weight, the transmittance of incident light is decreased. When the amount of the metal element is less than 0.01% by weight, it is difficult to improve the electric resistance of the transparent electrode. However, it is understood that the amount of the metal element may exceed 50% by weight in other aspects of the present invention.

Various methods of incorporating a metal element into the transparent conductive film can be used. Non-limiting examples and/or techniques include mixing, doping, film lamination, mesh lamination, complex formation, and/or ion injection. In other aspects of the present invention, additives such as a binder may be used together with the metal element in order to enhance the binding force of the metal element to the material forming the transparent substrate and/or the transparent conductive film.

Any transparent material may be used to form the transparent substrate constituting one component of the electrode for the photoelectric conversion device. Non-limiting examples of transparent materials include a glass substrate, and/or polymer materials such as polyethylene terephthalate, polycarbonate, polyimide, and/or polyethylene naphthalate.

Non-limiting examples of the transparent conductive film of the electrode for a photoelectric conversion device may be formed of tin oxide, tin oxide doped with impurities, zinc oxide, zinc oxide doped with impurities, semi-transparent nanoparticulate metal film, and/or a conductor formed from complexes thereof. To achieve high levels of conductivity, transparency and/or particularly heat resistance, tin oxides (e.g., SnO₂) are suitable, whereas to achieve lower costs, metal oxides including indium tin oxide (ITO) or zinc oxides (e.g., ZnO) are suitable. Non-limiting examples of the metal oxide also include fluorine-doped indium tin oxide (FTO).

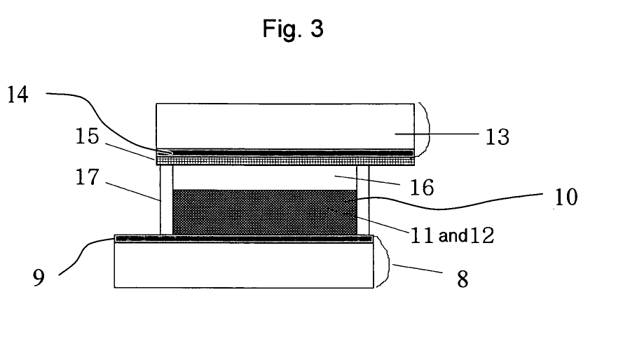

The electrode for a photoelectric conversion device according to an aspect of the present invention can be particularly useful for a dye-sensitized solar cell, the structure of which is illustrated in FIG. 3. The dye-sensitized solar cell has an electrolyte layer 16 interposed between an electrode portion (8, 9, and 10) and a counter electrode portion (13, 14, and 15). The electrode portion (8, 9, and 10) includes a transparent electrode 8 for a photoelectric conversion device according to an aspect of the present invention and a light absorption layer (10), while the counter electrode portion (13, 14, and 15) includes a transparent electrode 13 for a photoelectric conversion device according to an aspect of the present invention and a counter electrode 15, and the electrolyte layer 16 is interposed between the electrode portion (8, 9, and 10) and the counter electrode portion (13, 14, and 15). The light absorption layer (10) contains metal oxide particles 11 and dye molecules 12. In various aspects of the present invention, the electrode portion (8, 9, and 10) may be a semiconductor electrode. In other aspects of the present invention, only one of the transparent electrodes (8, 13) may be used as one of the pair of electrodes of the dye-sensitized solar cell.

The metal oxide particles 11 used for the dye-sensitized solar cell according to an aspect of the present invention may be in the form of semiconductor microparticles. In a non-limiting aspect of the present invention, the semiconductor microparticles may be an n-type semiconductor in which electrons in the conduction band serve as carriers in the photoexcited state to supply anodic current. Non-limiting examples of the n-type semiconductor include TiO₂, SnO₂, ZnO₂, WO₃, Nb₂O₅, Al₂O₃, MgO, TiSrO₃, and so on. The n-type semiconductor may be anatase type TiO₂. However, the kind of the metal oxide is not limited thereto, and these n-type semiconductors may be used individually or in combination thereof. It is desirable, but not required, for the metal oxide particles, and the exemplary semiconductor microparticles to have large surface areas so as to allow the dye molecules 12 that are adsorbed on the surface of the semiconductor microparticles to absorb more light, and to this end, the particle size of the semiconductor microparticles may be about 20 nm or less. However, it is understood that the semiconductor microparticles may be larger than 20 nm in other aspects of the present invention.

For the dye molecules 12 used for the dye-sensitized solar cell according to an aspect of the present invention, any dye that is used in the art of solar cells or photovoltaic cells may be used. In a non-limiting example, the dye may be a ruthenium complex. Examples of the ruthenium complex that can be used include RuL₂(SCN)₂, RuL₂(H₂O)₂, RuL₃, RuL₂, and so forth, and any combinations thereof, wherein L is 2,2′-bipyridyl-4,4′-dicarboxylate. However, the type of dye is not limited as long as the dye has a charge separating function and exhibits a sensitizing effect. Non-limiting examples of dyes other than ruthenium complexes include xanthine dyes such as Rhodamine B, Rose Bengal, eosine and erythrosine; cyanine dyes such as quinocyanine and kryptocyanine; basic dyes such as phenosaffranine, Cabri Blue, theosine and Methylene Blue; porphyrin dyes such as chlorophyll, zinc porphyrin and magnesium porphyrin; other azo dyes, phthalocyanine compounds, complexes such as Ru-trisbipyridyl, anthraquinone dyes, polycyclic quinine dyes, and so forth, and any combinations thereof. These compounds can be used individually or in combination of two or more species.

The thickness of the light absorption layer (10) may be 15 μm or less, for example, 1 to 15 μm. The light absorption layer (10) has a characteristic structure inducing high serial resistance, and an increase in the serial resistance leads to a decrease in the photoelectric conversion efficiency. Therefore, when the layer thickness is 15 μm or less, the function of the layer can be preserved while maintaining low serial resistance, thus preventing a decrease in the photoelectric conversion efficiency. However, it is understood that various aspects of the present invention the light absorption layer may have layer thicknesses of greater than 15 μm.

Non-limiting examples of the electrolyte layer 16 that is used for the dye-sensitized solar cells may be a liquid electrolyte, an ionic liquid electrolyte, an ionic gel electrolyte, a polymeric electrolyte, and/or a complex composed of any combination thereof. A non-limiting example of the electrolyte may be an electrolyte solution, which is formed to include the light absorption layer (10), or to have the electrolyte solution impregnated in the light absorption layer (10). Non-limiting examples of the electrolyte solution may be a solution of iodine in acetonitrile or the like. In fact, in various aspects of the present invention, any electrolyte capable of transferring holes can be used.

Although not required in all aspects of the present invention, the dye-sensitized solar cell may further include a catalyst layer (not shown), and this catalyst layer is intended to promote the oxidation-reduction reaction of the dye-sensitized solar cell. Non-limiting examples of the catalyst layer include platinum, carbon, graphite, carbon nanotubes, carbon black, p-type semiconductor, and/or a complex composed of any combination thereof. The catalyst layer is interposed between the electrolyte layer 16 and the counter electrode portion (13, 14 and 15). The catalyst layer may have a microporous structure with increased surface area, and for example, may be in the form of platinum black or in the form of carbonaceous microporous form. The platinum black form can be obtained by subjecting platinum to anodic oxidation or treatment with chloroplatinic acid, whereas the carbonaceous microporous form can be obtained by sintering carbon microparticles or calcining an organic polymer.

Hereinafter, the present invention will be described in more detail with reference to the following example and comparative example. However, these examples are provided for descriptive purposes only and are not intended to limit the present invention.

### COMPARATIVE EXAMPLE 1

Provided was a transparent conductive plastic substrate having a surface area of 1 cm², onto which indium-doped tin oxide was coated. A paste formed from titanium oxide particles having a particle size of about 7 to 25 nm was coated on the transparent conductive plastic substrate and subjected to a process of low temperature calcinations (150° C. or lower), so as to obtain a microporous titanium oxide film having a thickness of about 15 μm. Subsequently, the microporous titanium oxide film was subjected to a dye adsorption treatment using a solution of 0.3 mM Ru(4,4′-dicarboxy-2,2′-bipyridine)₂(NCS)₂ in ethanol at ambient temperature for 12 or more hours. Then, the dye-adsorbed microporous titanium oxide film was washed with ethanol and dried at ambient temperature. Accordingly, a photocathode was produced.

A counter electrode was produced by depositing a platinum (Pt) reducing electrode on a transparent conductor coated with a layer of indium-doped tin oxide by sputtering. A fine hole having a diameter of 0.75 mm was drilled in the counter electrode for the purpose of injecting an electrolyte solution.

A thermoplastic polymer film having a thickness of 60 μm was placed between the photocathode and the counter electrode, and the photocathode and the counter electrode were compressed at 100° C. for 9 seconds to be bonded together. An oxidation-reduction electrolyte was injected in through the fine hole formed in the counter electrode, and the fine hole was blocked using a sheet of cover glass and a thermoplastic polymer film. Accordingly, a dye-sensitized solar cell was produced. The oxidation-reduction electrolyte used for this process was a solution containing 21.928 g of tetrapropylammonium iodide and 1.931 9 of I₂ in a mixed solvent comprising 80% of ethylene carbonate and 20% of acetonitrile.

The short circuit current was evaluated from a current-voltage curve obtained using a light source of 100 mW/cm² after calibration with a silicon standard cell. The twice measured values of the photocurrent J_{sc} of the dye-sensitized solar cell of Comparative Example 1 were 4.12 mA/cm² and 5.24 mA/cm².

### EXAMPLE 1

A transparent conductive substrate was produced by coating a transparent conductive film of indium-doped tin oxide containing about 30% of copper (Cu) on a plastic substrate. A photocathode was produced in the same manner as in Comparative Example 1, and the experiment was performed in the same manner as in Comparative Example 1 using the same counter electrode and electrolyte solution. The photocurrent J_{sc} was measured twice under the same measuring conditions, and the measured values were 9.38 mA/cm² and 11.72 mA/cm².

It was clear that an improvement in the charge collection properties resulted from reduction of resistance in the transparent electrode of the dye-sensitized solar cell, and this was evidenced by an increase in the photocurrent J_{sc} (short circuit current). A comparison of the measurements obtained in Comparative Example 1 and Example 1 shows that larger values of photocurrent J_{sc} were obtained in Example 1 despite the same measuring conditions, and such an outcome resulted from lowered resistance of the substrate, and a subsequent improvement in the charge collection properties of the transparent electrode of Example 1.

In order to compare the two types of transparent electrodes for dye-sensitized solar cells, such as the transparent electrodes of Comparative Example 1 and that of Example 1, the surface resistance of each transparent electrode was measured. The surface resistance of the transparent electrode of Comparative Example 1 was 10 to 15Ω/□, whereas the surface resistance of the transparent electrode of Example 1 was 0.05 to 0.10 mΩ/□. These values show that even though the same plastic transparent conductive substrates were used, when the surface resistance of an electrode including a metal is significantly lowered, this lowered surface resistance leads to an increase in the short circuit current. The light transmittance of the transparent electrode of Comparative Example 1 was 84 to 85%, while the light transmittance of the metal-containing transparent electrode of Example 1 was 78 to 80%. In various aspects of the present invention, the metal elements may be dispersed in the transparent conductive film and/or may be formed as a layer on the surface of the transparent conductive film. In various aspects of the present invention, the metal element may be added to the transparent substrate in addition to and/or instead of the transparent conductive film.

As such, in the case of the transparent electrode including a metal layer according to an aspect of the present invention, the charge collection properties are enhanced by the decreased surface resistance of the transparent electrode, in spite of the decreased light transmittance, and thus the short circuit current is increased, as compared with conventional dye-sensitized solar cells. This implies that an improvement in the structure of the transparent electrode can lead to production of a dye-sensitized solar cell having superior photoelectric conversion efficiency compared to conventional dye-sensitized solar cells.

Aspects of the present invention enable production of a dye-sensitized solar cell having a higher photoelectric conversion efficiency than that of conventional dye-sensitized solar cells, by using a transparent electrode containing metal elements and having high light transmittance, thus lowering the surface resistance of the transparent electrode and enhancing the charge collection effect. As a result, the dye-sensitized solar cell of the present invention can be produced at lower costs.

Although a few aspects of the present invention have been shown and described, it would be appreciated by those skilled in the art that changes may be made in these aspects without departing from the principles and spirit of the invention, the scope of which is defined in the claims and their equivalents.

What is claimed is:

1. An electrode for a photoelectric conversion device, the electrode comprising a transparent substrate and a transparent conductive film, wherein the transparent conductive film contains an added metal element.

2. The electrode of claim 1, wherein the amount of the added metal element contained in the transparent conductive film is 0.01 to 50% by weight, based on the total amount of the components of the transparent conductive film.

3. The electrode of claim 1, wherein the added metal element contained in the transparent conductive film is at least one selected from the group consisting of the metals belonging to Group 13 and Group 14, and transition metals.

4. The electrode of claim 1, wherein the added metal element contained in the transparent conductive film is at least one selected from the group consisting of Al, Ni, Cr, Cu, Fe, Ti, Ta, Sn, In, Pt, Au, Ag and Ru.

5. A dye-sensitized solar cell comprising:
a pair of electrodes, at least one of which is the electrode of claim 1; and
a light absorption layer and an electrolyte formed between the pair of electrodes.

6. A dye-sensitized solar cell comprising:
a pair of electrodes, at least one of which is the electrode of claim 2; and
a light absorption layer and an electrolyte formed between the pair of electrodes.

7. A dye-sensitized solar cell comprising:
a pair of electrodes, at least one of which is the electrode of claim 3; and
a light absorption layer and an electrolyte formed between the pair of electrodes.

8. A dye-sensitized solar cell comprising:
a pair of electrodes, at least one of which is the electrode of claim 4; and
a light absorption layer and an electrolyte formed between the pair of electrodes.

9. The electrode of claim 2, wherein the added metal element contained in the transparent conductive film is Cu.

10. The electrode of claim 9, wherein the amount of Cu is 30% by weight of the transparent conductive film.

11. The electrode of claim 1, wherein the metal element is incorporated into the transparent conductive film by at least one of simple mixing, doping, film lamination, mesh lamination, complex formation, and ion injection.

12. The electrode of claim 11, further comprising a binder to enhance the binding force of the metal element to at least one of a material forming the transparent substrate and a material forming the transparent conductive film.

13. The electrode of claim 1, wherein the transparent substrate is formed of at least one of polyethylene terephthalate, polycarbonate, polyimide, polyethylene naphthalate, and a glass.

14. The electrode of claim 1, wherein the transparent conductive film is formed of at least one of tin oxide, tin oxide doped with impurities, zinc oxide, zinc oxide doped with impurities, semi-transparent nanoparticulate metal film, and a conductor formed from complexes thereof.

15. The dye-sensitized solar cell of claim 5, further comprising a light absorption layer formed between the pair of electrodes, wherein the light absorption layer includes metal oxide micro particles comprising at least one of TiO₂, SnO₂, ZnO₂, WO₃, Nb₂O₅, Al₂O₃, MgO, and TiSrO₃.

16. The dye-sensitized solar cell of claim 5, further comprising a light absorption layer formed between the pair of electrodes, wherein the light absorption layer includes dye particles comprising at least one of ruthenium complex including RuL₂(SCN)₂, RuL₂(H₂O)₂, RuL₃, and/or RuL₂, wherein L is 2,2′-bipyridyl-4,4′-dicarboxylate, xanthine dyes including Rhodamine B, Rose Bengal, eosine and/or erythrosine; cyanine dyes including quinocyanine and/or kryptocyanine, basic dyes including phenosaffranine, Cabri Blue, theosine, and Methylene Blue, porphyrin dyes including chlorophyll, zinc porphyrin, and magnesium porphyrin, azo dyes, phthalocyanine compounds, and complexes including Ru-trisbipyridyl, anthraquinone dyes, and polycyclic quinine.

17. The electrode of claim 1, wherein the surface resistance of the electrode is between about 0.05 to 0.10 mΩ/unit area.

18. A dye-sensitized solar cell, comprising a transparent electrode having a transparent conductive film formed on a transparent substrate, the transparent conductive film containing a metal component of the transparent conductive film, and an added metal element to reduce a surface resistance of the transparent electrode.

19. The dye-sensitized solar cell of claim 18, wherein the added metal is dispersed in the transparent conductive film

20. The dye-sensitized solar cell of claim 18, wherein the added metal increases the charge collecting property of the transparent electrode.

21. A method of forming an electrode of a dye-sensitive solar cell, comprising:
incorporating a metal element to a transparent conductive film;
coating the transparent conductive film having the incorporated metal element to a transparent substrate; and
calcining the transparent substrate having the incorporated metal element at a temperature of about 150° C.

22. The method of claim 21, wherein the metal element is Cu and the transparent conductive film is indium-doped tin oxide.

23. The dye-sensitized solar cell of claim 5, further comprising a catalyst layer formed between the electrolyte and one of the pair of electrodes to promote the oxidation-reduction reaction of the dye-sensitized solar cell.

24. The dye-sensitized solar cell of claim 23, wherein the catalyst layer is at least one of platinum, carbon, graphite, carbon nanotubes, carbon black, and a p-type semiconductor.

25. The dye-sensitized solar cell of claim 23, wherein the catalyst layer has a microporous structure with increased surface area, and is in the form of platinum black or in the form of carbonaceous microporous form.

26. The dye-sensitized solar cell of claim 25, wherein the platinum black form is obtained by subjecting platinum to anodic oxidation or treatment with chloroplatinic acid, and the carbonaceous microporous form is obtained by sintering carbon microparticles or calcining an organic polymer.
